(19) United States
(12) Patent Application Publication
(10) Pub. No.: US 2012/0056282 A1
(43) Pub. Date: Mar. 8, 2012

(54) MEMS Transducer for an Audio Device

(75) Inventors: Twan Van Lippen, Noordt-Brabant (NL); Geert Langereis, Eindhoven (NL); Josef Lutz, Rohrau (AT); Hilco Suy, Hulst (NL); Cas Van Der Avoort, Waalre (NL); Andreas Bernardus Maria Jansman, Brabant (NL)

(73) Assignee: KNOWLES ELECTRONICS ASIA PTE. LTD., Itasca, IL (US)

(21) Appl. No.: 13/262,609

(22) PCT Filed: Mar. 30, 2010
(86) PCT No.: PCT/IB2010/051370

§ 371 Date: Nov. 16, 2011

(30) Foreign Application Priority Data
Mar. 31, 2009 (EP) 09157025.9

(51) Int. Cl. H01L 29/84; H04R 31/00

(52) U.S. Cl. 257/416; 29/594; 257/E29.324

(57) ABSTRACT

A MEMS transducer (10) for an audio device comprises a substrate (12), a membrane (14) attached to the substrate (12), and a back-electrode (18) attached to the substrate (12), wherein a resonant frequency of the back-electrode (18) is matched to a resonant frequency of the membrane (14). Further, a method of manufacturing a MEMS transducer (19) for an audio device comprises attaching a membrane to a substrate (12), attaching a back-electrode (18) to the substrate (12), matching a resonant frequency of the back-electrode (18) to a resonant frequency of the membrane (14).

### FIELD OF THE INVENTION

The invention refers to a microelectromechanical system (MEMS) transducer for an audio device.

Further, the invention relates to a method of manufacturing a MEMS transducer for an audio device.

### BACKGROUND OF THE INVENTION

MEMS transducers may be designed as microphones used in mobile phones to convert a sound signal to an electrical output signal.

U.S. Pat. No. 6,812,620 B2 discloses a microphone of capacitor type which comprises an acoustically closed microphone back-chamber to which a rigid back-electrode and a membrane are fixed. The membrane covers the microphone back-chamber, and the back-electrode is arranged next to the membrane in a parallel way such that a small air gap is left between both the membrane and the back-electrode. The membrane and the back-electrode comprise conductive layers which form a capacitor. Further, the back-electrode comprises holes allowing for pressure release into the microphone back-chamber, whereby the back-electrode is acoustically transparent. An isolating support structure is provided between the back-electrode and the membrane which serves as electrical isolation between the membrane and the back-electrode.

Sound pressure forces the membrane to move at a frequency, equal to the frequency of the sound pressure wave. During this movement the membrane is displaced from its rest position such that the distance of the membrane from the back-electrode changes. This effect results in a modification of the capacitace of the “membrane/back-electrode”-capacitor which is converted to an electrical output signal, for instance a time dependent voltage.

However, the known microphone does not only respond to sound pressure waves, as described above, but also to movement of the body of the microphone. This undesired effect is called body noise and is caused by movement of the membrane and/or back-electrode in response to movement of the whole body. Thus, the noise level of the electrical output signal is increased considerably, making the MEMS transducer unsuitable for measurement of very small input signals.

### OBJECT AND SUMMARY OF THE INVENTION

It may be an object of the invention to provide a MEMS transducer for an audio device having a low level of body noise. It may be further an object of the invention to provide a method of manufacturing such a MEMS transducer for an audio device.

In order to achieve the object defined above, a MEMS transducer for an audio device and a method of manufacturing a MEMS transducer for an audio device according to the independent claims are provided. Advantageous embodiments are described in the dependent claims.

According to an exemplary aspect of the invention, a MEMS transducer for an audio device is provided, which comprises a substrate, a membrane attached to the substrate, and a back-electrode attached to the substrate, wherein a resonant frequency of the back-electrode is matched to a resonant frequency of the membrane.

According to an exemplary aspect of the invention, a method of manufacturing a MEMS transducer for an audio device is provided, the method comprising attaching a membrane to a substrate, attaching a back-electrode to the substrate, matching a resonant frequency of the back-electrode to a resonant frequency of the membrane. The term “transducer” may particularly denote any device that converts an input signal of one form into an output signal of another form. The one of the forms may be an acoustic form, and the other one of the forms may be an electric signal, for instance a signal characteristic for the audio content to be played back by a loudspeaker or a signal characteristic for acoustic waves captured by a microphone. The system may be denoted as an electroacoustic or acoustoelectric transducer. In this context, the term acoustic wave may be denoted as a pressure change that moves at the speed of sound. Such an acoustic wave may also be denoted as a sound wave transmitting sound. Particularly, such a transducer may be a microphone or a loud-speaker.

The term “MEMS” may particularly denote a microelectromechanical structure. For instance, an electrical signal may result in a specific motion of a movable component of the microelectromechanical structure (MEMS), or vice versa.

The term “attached to a substrate” used in this application may particularly denote any direct or indirect connection of an element, for instance the membrane or the back-electrode, and the substrate. In particular, the element and the substrate may be directly connected to one another or may be designed in a single pieced way. The element and the substrate may be securely fixed or detachably connected to one another. Further, the element and the substrate may be indirectly connected to one another via a further element.

In particular, the term “the resonant frequencies of the membrane and the back-electrode being matched to one another” may particular comprise the fact that both resonant frequencies, particularly mechanical resonance frequencies, are identical or close to one another.

The term “substrate” may be used to define generally the elements for layers that underlie and/or overlie a layer or portions of interest. Also, the substrate may be any other base on which a layer is formed, for example a semiconductor wafer such as a silicon wafer or silicon chip. Substrates from other materials such as plastic, glass, ceramics, etc. are possible as well. In particular, the substrate may be part of a back-chamber of the transducer. Alternatively, the substrate may be a single element, for instance a frame that is connected to the back-chamber.

Adapting a, for instance fundamental, resonant frequency of the back-electrode of a MEMS transducer to a resonant frequency of the membrane of the MEMS transducer yields a reduction of the body noise of the MEMS transducer, since the back-electrode and the membrane respond in a synchronous way to movements of the whole MEMS tranducer and there is no modification of the capacitance between back-electrode and membrane. Here, the term “body noise” may particularly denote any output signals of the MEMS transducer which are caused by mechanical vibrations of the membrane and the back-electrode upon moving the MEMS transducer for instance during its use. Mechanical vibrations may lead to unintentional movements of the membrane and the back-electrode relative to one another which may superimpose to the movement of the membrane due to an input signal. These unintentional displacements of the membrane from the back-electrode cause additional signals that may add to the desired signal caused by the input signal. Thus, upon the resonant frequencies of the back-electrode and the membrane being matched to one another, the membrane and the back-electrode synchronously move in terms of a co-phased motion of equal amplitude, whereby the relative distance between the membrane and the back-electrode remains unchanged upon mechanical vibrations. Thus, no further body noise signals due to unintentional movements of the back-electrode and the membrane are created.

A gist of exemplary aspects of the invention may be seen in the fact that the MEMS transducer will be suitable for measurement of small input signals, since the undesired body noise of the MEMS transducer caused by mechanical vibrations of the back-electrode and the membrane is suppressed or cancelled out. This effect is achieved by adapting the resonant frequency of the back-electrode to the resonant frequency of the membrane such that the displacement of the back-electrode and the membrane from their remaining positions is synchronous. In particular, no further unintentional output signal is created by an unintentional relative motion of the back-electrode and the membrane which may be detected as body noise.

Further, the MEMS transducer may be versatilely used in various electrical devices, since its shows an excellent performance in terms of usefulness for the measurement of small signals as the body noise due to movements of the transducer may be totally cancelled out.

Next, further aspects of exemplary embodiments of the MEMS transducer are described. However, these embodiments also apply to the method.

According to an exemplary embodiment of the MEMS transducer, a stiffness of the back-electrode is adapted to match the resonant frequency of the back-electrode to the resonant frequency of the membrane.

According to an exemplary embodiment of the MEMS transducer, a mass and/or a stress of the back-electrode is adapted to match the resonant frequency of the back-electrode to the resonant frequency of the membrane.

These measures, in particular the change in the stiffness, the mass and/or the stress of the back-electrode, advantageously allows for easily modifying the frequency of the back-electrode such that the frequency of the back-electrode may be adapted to the frequency of the membrane, since these parameters are decisive for determining the (resonant) frequency of the back-electrode. The term “stiffness” may denote the technical constant being inverse to the compliance and/or simply describe a mechanical material property such as the bending flexibility.

In particular, the stiffness of the back-electrode may be decreased by changing the stress of the back-electrode. As the person skilled in the art may know, these parameters may depend on one another according to the following formulas: In one-dimensional analysis of the back-electrode and/or membrane motion, a force F acting on the back-electrode and/or the membrane may correspond to m*a, with m denoting the mass and a the acceleration. The excursion of the back-electrode and/or the membrane x may be proportional to C*F under the condition the frequency of the acceleration is well below of the resonant frequencies. In this context, C may denote the compliance. Further, the (resonant) frequency f may relate to the compliance via the formula f=(1/2π)*1/(Cm)^{1/2}, resulting in x being proportional to a/ω², with w being the angular frequency. The difference in excursion of the back-electrode and the membrane in response to a force acting both on the membrane and the back-electrode, Δx may be proportional to a*((1/ω²ₘₑₘ)−(1/ω²_{be})), with ωₘₑₘ and ω_{be} being the angular frequency of the membrane and the back-electrode, respectively. Comparing a modified back-electrode and a stiff or rigid back-electrode (stiff means ω²_{be} goes to infinity) to one another, the ratio of the corresponding excursions may read Δx/Δx_{stiff}=1−(fₘₑₘ/f_{be})².

According to an exemplary embodiment of the MEMS transducer, an outer rim of the back-electrode is thinned as compared to a central part of the back-electrode. Thus, mass reduction of the back-electrode may be easily accomplished during for instance manufacturing the MEMS transducer. In particular, the outer rim of the back-electrode may be thinned by tapering the outer rim of the back-electrode or by introducing a step-like change in thickness of the back-electrode. Limitation of the thinned design of the outer rim is given by a maximum stress built up in the back-electrode upon being bended due to the mechanical vibrations. Further, with the deflection profile of the membrane being sinusoidal, the deflection of the outer rim may hardly influence the change in the capacity due to air gap modulation.

The back-electrode may comprise any regular or irregular shape. In particular, the back-electrode may be designed in a circular way such that the outer rim of the back-electrode represents an outer ring element of the back-electrode.

According to an exemplary embodiment of the MEMS transducer, one or more openings are provided in an outer rim of the back-electrode. Thus, mass reduction of the outer rim of the back-electrode is accomplished, in order to enable matching the resonant frequencies of both the membrane and the back-electrode. Further, the stiffness of the back-electrode is decreased, whereby moving in terms of bending of the back-electrode is enabled. The design modification of the outer rim of the back-electrode may further not alter the performance of the back-electrode as capacitor plate. In particular, the openings may be formed as for instance holes or recesses of regular or irregular shape in the outer rim of the back-electrode. Further, the openings may be equally or unequally distributed along the extent of the outer rim of the back-electrode.

According to an exemplary embodiment of the MEMS transducer, a thickness of at least a central part of the back-electrode is uniform, whereby stress, being induced during bending the back-electrode, at locations of thickness variations, especially at step-like thickness variations, is prevented. Further, the performance of the “membrane/back-electrode”-capacitor is maintained, since unintentionally changes in the capacitance which would falsify the output signal are prevented. In particular, the thickness of the total back-electrode may be uniform.

According to an exemplary embodiment of the MEMS transducer, a diameter of a central part of the back-electrode is dimensioned to be at least 90% of a diameter of the membrane. Thus, the capacity of the back-electrode is unaffected when changing, especially decreasing, the diameter of the back-electrode. The deflection profile of the back-electrode may be then similar to the deflection profile of the membrane. In particular, increasing the diameter of the back-electrode may be possible and only be limited by the MEMS transducer size.

According to an exemplary embodiment of the MEMS transducer, holes are provided in a central part of the back-electrode, wherein the holes occupy an area that is less than 25% of an area of the central part of the back-electrode. Here, the area of the central part of the back-electrode may denote the area of the central part of the back-electrode without holes. The applicants found out that this particular condition may allow for the back-electrode being acoustically transparent while the resonance frequency of the back-electrode does not change, since the Young modulus and the mass of the back-electrode decreases in the same way.

According to an exemplary embodiment of the MEMS transducer, a suspension is provided between the substrate and the back-electrode, wherein the suspension is adapted such that the resonant frequency of the back-electrode may be matched to the resonant frequency of the membrane. In particular, the suspension may be adapted such that a conjoint resonant frequency of the back-electrode and the suspension is matched to the resonant frequency of the membrane. This measure allows a motion of the back-electrode in every direction, as the suspension may be further bended upon mechanical vibrations. The conjoint frequency of the suspension and the back-electrode may also be dependent on the shape and/or the material of the suspension. In particular, the suspension may be made of any suitable material, e.g. of an elastic material.

According to an exemplary embodiment of the MEMS transducer, the back-electrode and the suspension comprise the same material. This measure advantageously allows for an easy manufacturing process of the MEMS transducer, since these elements may be manufactured during the same manufacturing step. Further, matching the resonant frequency of both the suspension and the back-electrode to the resonant frequency of the membrane may be easily performed, since equal parameters, for instance stiffness, mass and stress, of the back-electrode and the suspension may have to be taken into account during manufacturing the MEMS transducer. In particular, the suspension and the back-electrode may be designed in a single pieced way, thus further facilitating the manufacturing process.

According to an exemplary embodiment of the MEMS transducer, a suspension is arranged at least partially along a circumference of the back-electrode connecting the substrate and the back-electrode. This kind of suspension arrangement allows for a mechanically stable MEMS transducer design and a uniform motion of the back-electrode.

According to an exemplary embodiment of the MEMS transducer, the suspension is designed as straight spring arms extending from the back-electrode in a radial way. The spring arms may have a spring constant dependent on the shape and/or the material of the spring arms.

According to an exemplary embodiment of the MEMS transducer, the suspension is designed as spring arms which run in a way matching a circumferential shape of the back-electrode.

These configurations of the suspension may allow a motion of the back-electrode in three degrees of freedom. In particular, the spring arms may allow for rotational movement of the back-electrode upon mechanical vibrations. In particular, the spring arms may be designed spiral-like, tangentially extending from the back-electrode and interconnecting the back-electrode and the substrate. In particular, the spring arms may be arranged at opposed positions along the circumference of the back-electrode, whereby a mechanical stable connection between the substrate and the back-electrode is guaranteed. According to an exemplary embodiment of the MEMS transducer, a difference in the resonant frequency of the membrane and the resonant frequency of the back-electrode is less than 20%, preferably less than 5%, further preferably less than 1%. This measure allows a low level of body-noise. A higher degree of frequency matching may allow a better body noise suppression. For instance, in case the difference in the resonant frequencies of membrane and the back-electrode is less than 20%, a 10 dB improvement in noise suppression may be achieved. Matching the resonant frequency of the back-electrode within 5% to the resonant frequency of the membrane, body noise of approximately 20 dB may be cancelled out. A higher degree of frequency matching may yield a further improved body noise cancellation.

According to an exemplary embodiment of the MEMS transducer, the transducer is adapted as one of the group consisting of a MEMS microphone and a MEMS loudspeaker. The MEMS microphone and the MEMS loudspeaker represent particular embodiment of the MEMS transducers. In particular, the MEMS microphone may be a capacitor type MEMS microphone. The detection mechanism of the MEMS microphone may be based on an optical detection mechanism, an electrets detection mechanism, an electromechanical detection mechanism, or an electrodynamical detection mechanism.

For instance, the transducer according to an exemplary aspect of the invention may be implemented in an audio device selected of the group consisting of an audio surround system, a mobile phone, a headset, a headphone playback apparatus, a loudspeaker playback apparatus, a hearing aid, a television device, a video recorder, a monitor, a gaming device, a laptop, an audio player, a DVD player, a CD player, a harddisk-based media player, a radio device, an internet radio device, a public entertainment device, an MP3 player, a hi-fi system, a vehicle entertainment device, a car entertainment device, a medical communication system, a medical device, a blood probe, a body-worn device, a speech communication device, a home cinema system, a home theatre system, a flat television apparatus, an ambiance creation device, a subwoofer, an acoustic measurement system, a sound level meter, a studio recording system, and a music hall system. However, these applications are only exemplary, and other applications in many fields of the art are possible and in the frame of the invention.

Summarizing, according to an exemplary aspect of the invention, a MEMS transducer is provided which comprises a membrane and back-electrode both being attached to a substrate, for instance a back-chamber of the MEMS transducer. The stiffness of the back-electrode is reduced by decreasing the mass of the back-electrode and releasing stress of the back-electrode such that, upon mechanical vibrations, a co-phased motion with equal amplitudes of the back-electrode and the membrane is enabled. In one configuration, an outer rim of a circular back-plate is thinned in that a step-like thickness decrease of the back-electrode is provided. Alternatively, the outer rim of the back-electrode may comprise holes and/or half elliptical recesses tapering to a center of the back-electrode. In a further configuration, a suspension is provided between the back-electrode and the substrate which may be designed as straight and/or bended spring arms. In particular, the holes may be incorporated in outer rim of the back-electrode, and the back-electrode is suspended by spring arms interconnecting the outer rim and the substrate.

Summarizing, according to an exemplary aspect of the invention, a method of manufacturing a transducer for an audio device is provided, wherein a membrane is attached to a substrate, a back-electrode is attached to the substrate, and a resonant frequency of the back-electrode is matched to a resonant frequency of the membrane.

The aspects defined above and further aspects of the invention are apparent from the examples of embodiment to be described hereinafter and are explained with reference to these examples of embodiment. It should be noted that features described in connection with one exemplary embodiment or exemplary aspect may be combined with other exemplary embodiments and other exemplary aspects.

### BRIEF DESCRIPTION OF THE DRAWINGS

The invention will be described in more detail hereinafter with reference to examples of embodiment but to which the invention is not limited.

FIG. 1 schematically illustrates a cross-sectional side view of a MEMS micro-phone according to the invention.

FIG. 2 schematically illustrates a plain view of the membrane and the back-electrode of the MEMS microphone in FIG. 1.

FIG. 3a schematically illustrates a cross-sectional side view of an embodiment of the back-electrode of the MEMS microphone in FIG. 1.

FIG. 3b illustrates a deflection profile of the back-electrode in FIG. 3a.

FIG. 4a-d schematically illustrates further embodiments of the back-electrode in FIG. 3a.

### DESCRIPTION OF EMBODIMENTS

The illustration in the drawing is schematically. In different drawings, similar or identical elements are provided with similar or identical reference signs.

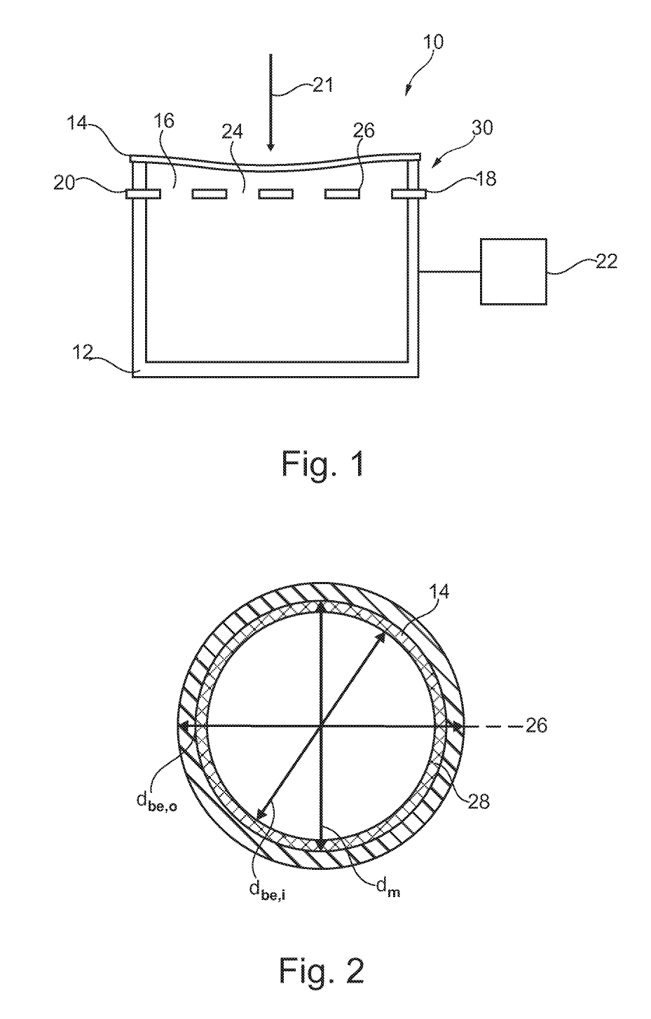

FIG. 1 schematically shows a cross-sectional side view of a MEMS microphone 10 according to the invention. The MEMS microphone 10 is of capacitor type and may be part of a mobile phone. The MEMS microphone 10 has low body noise due to mechanical vibrations of its elements, in particular its membrane and its back-electrode, since the back-electrode is designed to have a synchronous mechanical response on mechanical vibration of the whole microphone 10.

The MEMS microphone 10 comprises a cylindrical back-chamber 12 which serves as a resonator of the MEMS microphone 10. Further, a membrane 14 or diaphragm covers an opening 16 of the back-chamber 12. The membrane 14 is fixed to a circumference of the back-chamber 16. A back-electrode 18 is arranged within the back-chamber 12 next to the membrane 14 in such a way that the membrane 14 and the back-electrode 18 are spaced apart and run in a parallel way respecting one another. The back-electrode 18 is directly fixed to the back-chamber 12 in terms of an outer ending 20 of the back-electrode 18 being clamped between upper and lower parts of a side wall of the back-chamber 12. Alternatively, the back-chamber 12 may comprise a circumferential recess in which the outer ending 20 of the back-electrode 18 is received.

The cross-section of the back-chamber 12, the membrane 14 and the back-electrode 18 may have any suitable form such as circular, rectangular, elliptical forms etc. The shape of the membrane 14 and the back-electrode 18 may be adapted to the shape of the opening 16 of the back-chamber 12.

The membrane 14 and the back-electrode 18 are made of a conductive material or may be covered with a layer of a conductive material. Hence, the membrane 14 and the back-electrode 18 form a capacitor with the membrane 14 and the back-electrode 18 acting as capacitor plates.

During usage of the microphone 10, air pressure 21 caused by a sound signal causes the membrane 14 to oscillate at a certain frequency. Depending on the change in distance of the displaced membrane 14 from the back-electrode 18 an electrical signal is produced and is transmitted to a signal convertor 22 for outputting a converted signal. The back-electrode 18 is acoustically transparent in that it comprises holes 24 in a central part 26 of the back-electrode 18 such that air can pass through the back-electrode 18 into the back-chamber 12.

The area of the hole perforation of the back-electrode 18 is less than 25% of the total area of the central part 26 of the back-electrode 18 such that the performance of the “membrane/back-electrode”-capacitor remains unaffected.

A movement of the MEMS microphone 10 induces mechanical vibrations in the MEMS microphone 10 such that the membrane 14 and the back-electrode 18 perform movements which are not synchronised to one another. These unintentional displacements of the membrane 14 from the back-electrode 18 may result in noise signals. In order to suppress such body noise, the resonant frequency of the back-electrode 18 is matched to the resonant frequency of the membrane 14.

Body noise suppression is accomplished in the MEMS microphone 10 by defining an outer rim 28 which can be modified in design for decreasing the stiffness of the back-electrode 18 and/or decreasing the mass of the back-electrode 18 and/or releasing stress of the back-electrode 18.

FIG. 2 illustrates the dimension proportions of the outer rim 28 of the back-electrode 18 with respect to the membrane 14. In this figure a circular layout is suggested, but the invention is not limited to this shape. Conventionally, the back-electrode 18 and the membrane 14 are equally sized such that a diameter dₘ of the membrane 14 and a diameter d_{be} of the back-electrode 18 are equal. The outer rim 18 may size up to 10% of the diameter dₘ of the membrane such that an inner diameter d_{be,i} of the central part 26 of the back-electrode 18 is at least 90% of the diameter dₘ of the membrane 14. The outer diameter d_{be,o} of the back-electrode 18 is limited by the maximum size of the MEMS microphone 10. For instance, the central part 26 of the back-electrode 18 may comprise an inner diameter d_{be,i} of 0.9 dₘ, whereas the outer rim 18 is enlarged in such a way that the outer diameter d_{be,o} of the back-electrode 18 is by 5% larger than the diameter dₘ of the membrane 14.

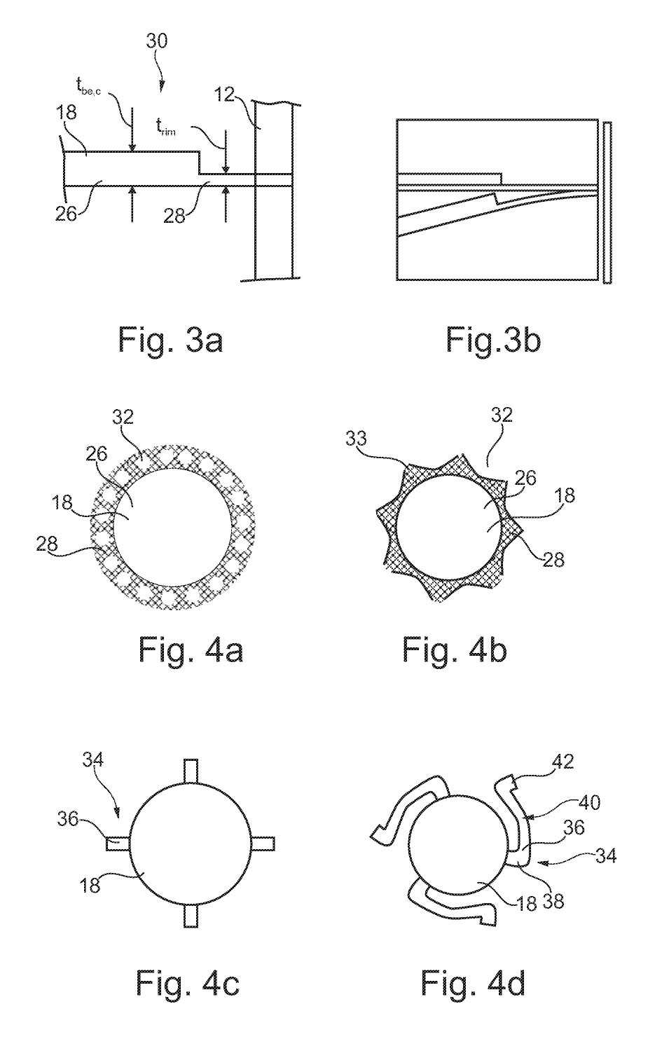

FIG. 3a shows an enlarged view of the region 30 in FIG. 1 illustrating one embodiment of the back-electrode 18 being fixed to the back-chamber wall. The vertical cross-section of the mass-reduced back-electrode 18 is step-like, wherein a thickness t_{be,c} of the central part 26 of the back-electrode 18 is approximately three times larger than a thickness tᵣᵢₘ of the thinned outer rim 28 of the back-electrode 18. The thickness t_{be,c} of the central part 26 of the back-electrode 18 is uniform over the entire extent of the central part 26 of the back-electrode 18 such that the capacity of the membrane 14 and the back-electrode 18 is left unaffected by the thickness profile and thus the electrical signal is not falsified.

FIG. 3b shows the result of a corresponding finite element simulation of the stress distribution of the partly thinned back-electrode 18 which comprises an initial stress of 50 MPa. Stress, built-up in the back-electrode 18 due to a stress redistribution at the step-like thickness edge, leads to local stress values of approximately 150 MPa at the thickness edge. The thinned outer rim 28 thus represents the location with the largest deflection occurring upon moving the back-electrode 18. It may be seen in FIG. 3b that the outer rim 28, especially close to the thickness edge, is highly mechanically unstable and thus a serious point of attention concerning the reliability of the back-electrode 18. In this way, the ratio of the thickness t_{be,c} of the central part 26 of the back-electrode 18 and the thickness tᵣᵢₘ of the outer rim 28 may be accordingly adapted for increasing the mechanical stability of the back-electrode 18.

Further, only parts of the outer rim 28 of the back-electrode 18 may be thinned, wherein the thinned regions may be equally distributed along the extent of the outer rim 28 of the back-electrode 18. Thinning of the outer rim 28 of the back-electrode 18 may also be achieved by tapering the outer rim 28 towards the outer ending 20 of the back-electrode 18. In a further embodiment of the back-electrode 18 illustrated in FIG. 4a, the back-electrode 18 comprises a uniform thickness t_{be} over its entire extent, wherein the outer rim 28 (shadowed region) comprises circular, equally distributed through-going openings 32. Thus, the mass as well as the stress distribution of the back-electrode 18 can be modified, in order to match the resonant frequency of the back-electrode 18 to the resonant frequency of the membrane 14. The shape of the openings 32 is a further point of inducing stress into the back-electrode 18. Sharp edges of the openings 32 may have to be omitted in the back-electrode design. The back-electrode 18 is fixed to the back-chamber 12 along its total circumference.

Referring to FIG. 4b, a further embodiment of the back-electrode 18 is shown. The back-electrode 18 is star-like shaped in that the outer rim 28 of the back-electrode 18 comprises half-elliptical recesses 32 tapering towards the centre of the back-electrode 18. Thus, the back-electrode 18 is only fixed to the back-chamber 12 at fixing points 33 of the outer rim 28. The resonant frequency of the back-electrode 18 may be varied by the number of the fixing points 33 and/or the shape of the fixing points 33. The thickness t_{be} of the back-electrode is also uniform over its entire extent.

Further, body noise suppression may be accomplished by suspending the back-electrode 18, in order to mechanical decouple both the membrane 14 and the back-electrode 18 from the back-chamber 12.

Thus, the embodiment of the back-electrode 18 shown in FIG. 4b represents a transition to further embodiments of the back-electrode 18 shown in FIG. 4c, d which do not comprise an outer rim 28, but are connected to the back-chamber 12 via suspensions 34. In both configurations, the back-electrode 18 is circular shaped having a uniform thickness t_{be} over its entire extent. The suspension 34 shown in FIG. 4c is designed as four straight spring arms 36, in order to allow bending of the back-electrode 18 in three degrees of freedom. The spring arms 36 are attached to the back-electrode 18 at opposed positions which are displaced to one another by 90°. The suspension 34 illustrated in FIG. 4d comprises three spring arms 36 with first ending portions 38 of the spring arms 36 extending from the back-electrode 18 in an almost radial way. Central portions 40 of the spring arms 36 run in a way matched to a circumferential shape of the back-electrode 18, wherein bending regions are provided in middle parts of the central portions 40 of the spring arms 36. Ending portions 42 of the spring arms 36 being fixed to the substrate 12 also extend in a radial way with respect to the back-electrode 18. Such a configuration of the spring arms 36 represent an excellent measure for allowing the back-electrode 18 moving in three degrees of freedom. In particular, rotational movement of the back-electrode 18 is enabled. Further, the spring arms 36 may be spiral-like shaped extending tangentially from the back-electrode 18. Due to the shape of the suspension 34 a diameter of the back-electrode 18 in FIG. 4d may be smaller than a diameter of the back-electrode 18 in FIG. 4c. Thus, intrinsic stress of the back-electrode may be further reduced.

Further, the spring arms 36 are made of an elastic material, in order to improve the possibility of tuning the resonant frequency of the back-electrode 18.

The spring arms 36 and the back-electrode 18 are made of the same material such that manufacturing of the MEMS microphone 10 is facilitated.

The spring arms 36 comprise a spring constant which may be determined by the shape and/or the material of the spring arms 36. Frequency matching of the resonant frequency of the back-electrode 18 and the resonant frequency of the membrane 14 may thus easily performed.

In general, in case a difference between the resonant frequency of the back-electrode 18 and the resonant frequency of the membrane 14 is less than 20%, a 10 dB improvement in noise suppression is achieved. Matching the resonant frequency of the back-electrode 18 within 5% to the resonant frequency of the membrane 14 a noise improvement of about 20 dB is enabled. Preferably the difference between the resonant frequency of the back-electrode 18 and the membrane 14 is less than 1% yielding an almost complete body noise cancellation.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. A MEMS transducer for an audio device, the MEMS transducer comprising:
a substrate,
a membrane attached to the substrate, and
a back-electrode attached to the substrate, wherein a resonant frequency of the back-electrode is matched to a resonant frequency of the membrane.

2. The MEMS transducer according to claim 1, wherein a stiffness of the back-electrode is adapted to match the resonant frequency of the back-electrode to the resonant frequency of the membrane.

3. The MEMS transducer according to claim 1, wherein a mass and/or a stress of the back-electrode is adapted to match the resonant frequency of the back-electrode to the resonant frequency of the membrane.

4. The MEMS transducer according to claim 1, wherein an outer rim of the back-electrode is thinned as compared to a central part of the back-electrode.

5. The MEMS transducer according to claim 1, wherein one or more openings are provided in an outer rim of the back-electrode.

6. The MEMS transducer according to claim 1, therein a thickness (t_{be,c}) of at least a central part of the back-electrode is uniform.

7. The MEMS transducer according to claim 1, wherein a diameter (d_{be,i}) of a central part of the back-electrode is dimensioned to be at least 90% of a diameter (dₘ) of the membrane.

8. The MEMS transducer according to claim 1, wherein holes are provided in a central part of the back-electrode, wherein the holes occupy an area that is less than 25% of an area of the central part of the back-electrode.

9. The MEMS transducer according to claim 1, wherein a suspension is provided between the substrate and the back-electrode, wherein the suspension is adapted such that the resonant frequency of the back-electrode is matched to the resonant frequency of the membrane.

10. The MEMS transducer according to claim 9, wherein the back-electrode and the suspension comprise the same material.

11. The MEMS transducer according to claim 1, wherein a suspension is arranged at least partially along a circumference of the back-electrode connecting the substrate and the back-electrode.

12. The MEMS transducer according to claim 9, wherein the suspension is designed as straight spring arms extending from the back-electrode in a radial way.

13. The MEMS transducer according to claim 9, wherein the suspension is designed as spring arms which run in a way matching a circumferential shape of the back-electrode.

14. The MEMS transducer according to claim 1, wherein a difference in the resonant frequency of the membrane and the resonant frequency of the back-electrode is less than 20%, preferably less than 5%, further preferably less than 1%.

15. The MEMS transducer according to claim 1, adapted as one of the group consisting of a MEMS microphone and a MEMS loudspeaker.

16. A method of manufacturing a MEMS transducer for an audio device, the method comprising:
attaching a membrane to a substrate,
attaching a back-electrode to the substrate, matching a resonant frequency of the back-electrode to a resonant frequency of the membrane.
